(19) United States
(12) Patent Application Publication
(10) Pub. No.: US 2011/0269075 A1
(43) Pub. Date: Nov. 3, 2011

(54) METHOD OF FABRICATING COLOR FILTER WITH FLEXIBLE SUBSTRATE

(75) Inventors: CHUNG-WEI WANG, Tu-Cheng (TW); CHIU-HSIUNG LIN, Tu-Cheng (TW); CHUN-TSU LAI, Tu-Cheng (TW); MING-FENG YU, Tu-Cheng (TW)

(73) Assignee: HON HAI PRECISION INDUSTRY CO., LTD., Tu-Cheng (TW)

(21) Appl. No.: 13/015,879

(22) Filed: Jan. 28, 2011

(30) Foreign Application Priority Data
Apr. 30, 2010 (CN) 201010161089.1

(51) Int. Cl. G03F 7/20

(52) U.S. Cl. 430/321

(57) ABSTRACT

A method of fabricating a color filter includes steps of forming a transparent-matrix on a flexible and transparent substrate for dividing the substrate to a plurality of pixel regions; printing the a plurality of pixel regions with color ink; and curing the ink to form a plurality of color filters on the surface of the substrate. The light transmittance ability of the color filter can be effectively improved by forming a transparent-matrix instead of a black-matrix on the substrate.

### BACKGROUND

1. Technical Field

The present disclosure relates to a method of fabricating a color filter, especially to a method of fabricating a color filter with a flexible substrate.

2. Description of Related Art

Electrophoretic display devices have attributes of good brightness and contrast, wide viewing angles, state bistability, and low power consumption, as compared with liquid crystal displays. Nowadays, electrophoretic display devices are capable of displaying colorful images in two ways: the first way is by controlling each pixel to display a desired color by primary color mixing, such as RGB color mixing or YMC color mixing; and the second way is by covering the electrophoretic display with a color filter.

A fabrication method for forming a color filter layer by inkjet printing has been developed recently. With this conventional fabrication method, first, a black matrix is formed on a glass substrate to define a plurality of sub-pixel regions. An inkjet printing process is then performed to inject a color ink (red, green, or blue) to fill the sub-pixel regions defined by the black matrix. Next, a thermal baking process may be performed to solidify the color ink.

When the color filter is stacked on the electrophoretic display, inner gas-holes will be produced because the color filter is formed on the glass substrate and the electrophoretic display is flexible. The above conventional fabrication method, however, it's not suitable to fabricate the color filter on a flexible substrate because the material of the flexible substrate does not have good thermostability and cannot be baked in the thermal baking process.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a flowchart of a process of fabricating a color filter with flexible substrate in accordance with an exemplary embodiment.

FIG. 2 is a sub-flowchart of the process in FIG. 1 according to a first embodiment.

FIGS. 3A-3C are schematic cross-sectional views illustrating a process of fabricating a color filter with flexible substrate according to the first embodiment of FIG. 2.

FIG. 4 is a schematic view of the photo mask according to the first embodiment of FIG. 2.

FIG. 5 is a sub-flowchart of the process in FIG. 1 according to a second embodiment.

FIGS. 6A-6D are schematic cross-sectional views illustrating a process of fabricating a color filter with flexible substrate according to the second embodiment of FIG. 5.

FIG. 7 is a schematic view of an electronic paper having a color filter with flexible substrate.

### DETAILED DESCRIPTION

The disclosure, including the accompanying, is illustrated by way of example and not by way of limitation. It should be noted that references to “an” or “one” embodiment in this disclosure are not necessarily to the same embodiment, and such references mean at least one.

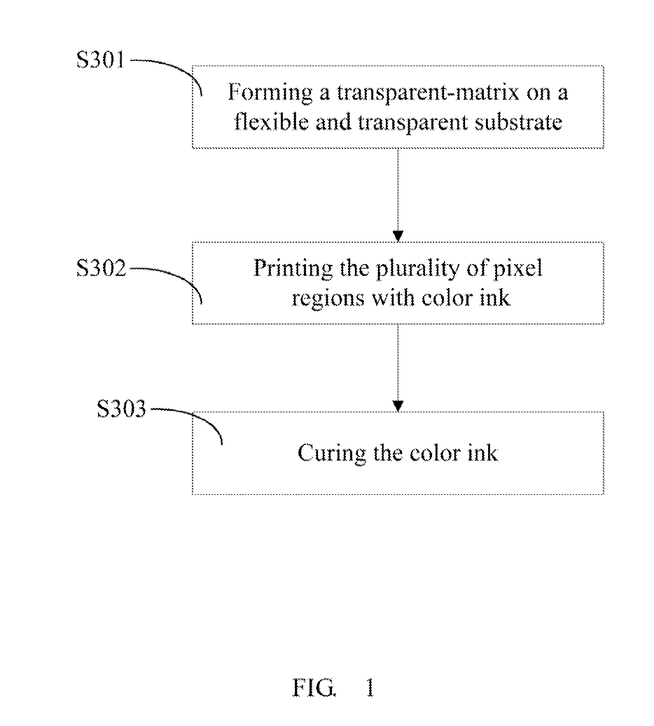

Referring to FIG. 1, a flowchart is applied in a process of fabricating a color filter.

In step S301, forming a transparent-matrix on a flexible and transparent substrate for dividing the substrate to a plurality of pixel regions, with the transparent-matrix and the pixel regions having different wettability.

In step S302, printing the a plurality of pixel regions with color ink.

In step S303, curing the color ink.

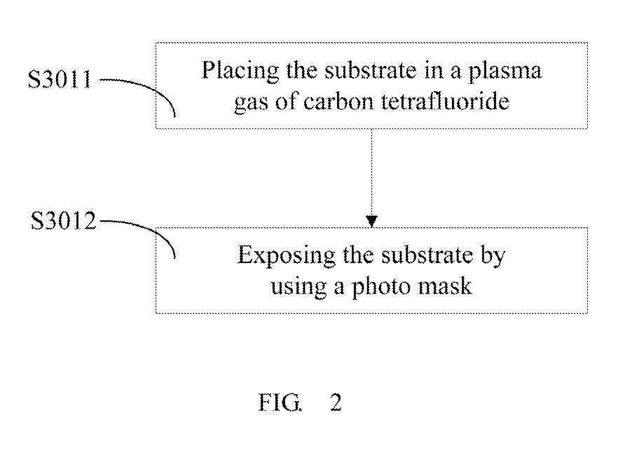

Referring to FIG. 2, a sub-flowchart of the step 301 in FIG. 1 is applied in the process of fabricating a color filter with flexible substrate according to a first embodiment.

In step S3011, placing the substrate in a plasma gas of carbon tetrafluoride.

In step S3012, shielding some portion of the substrate by a photo mask and exposing other portion in the plasma gas of carbon tetrafluoride.

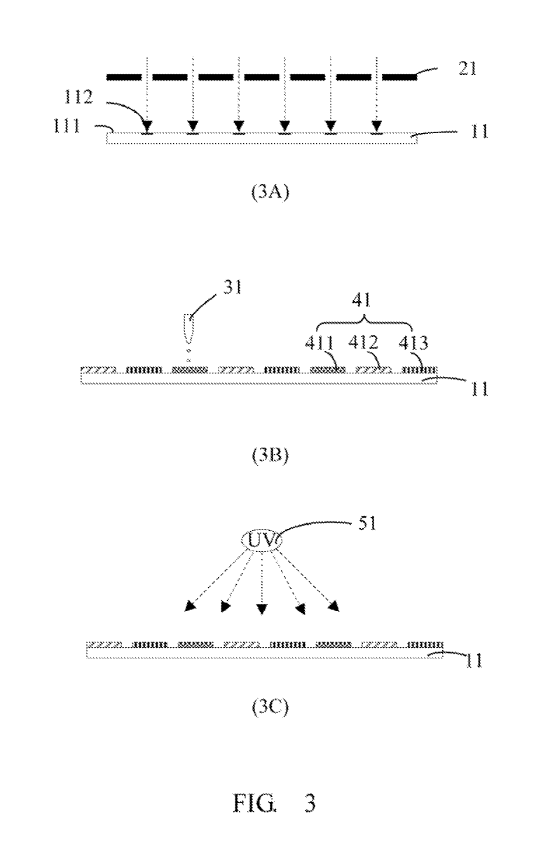

FIG. 3A-3C are schematic cross-sectional views illustrating a process of fabricating a color filter according to the first embodiment.

Referring to FIG. 3A, the substrate 11 is exposed in the gas of carbon tetrafluoride by using the photo mask 21. The substrate 11 is made of flexible plastic with high intensity, such as polyisoprene (PI), polycarbonate (PC), or polyethylene terephthalate (PET). In this embodiment, the substrate 11 is made of PC.

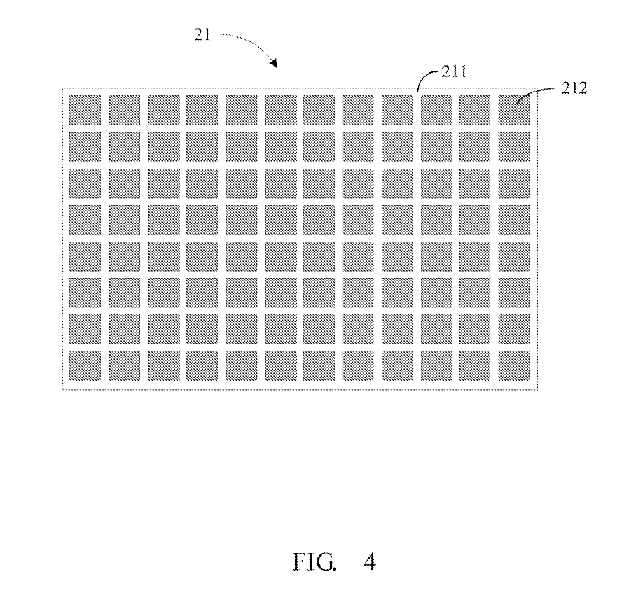

Referring to FIG. 4, the photo mask 21 includes a plurality of photic zones 211, the plurality of photic zones 211 divide the photo mask 21 into a plurality of photoresistive zones 212. Light rays can pass through the photic zones 211 and reach the surface of the substrate 11. The surface of the substrate 11 where not shielded by the photoresistive zones 212 of the photo mask 21 is infiltrated by the plasma gas of carbon tetrafluoride under the photo catalysis of the light rays, to form the transparent matrix 112 with high hydrophobicity and low surface energy. The transparent matrix 112 divides the substrate 11 to a plurality of pixel regions 111.

The transparent matrix 112 and the pixel regions 111 have different wettability, in the first embodiment, the transparent matrix 112 is hydrophobic and the pixel regions 111 is hydrophilic. Whether the material is hydrophobic or hydrophilic is determined by a parameter of a material: contact angle. The contact angle less than 90° (low contact angle) usually indicates the material is hydrophilic, and the fluid dropped on the material can spread over a large area of the surface of the material. Contact angles greater than 90° (high contact angle) generally means that the material is hydrophobic, and the fluid will minimize the contact with the surface of the material and form a compact liquid droplet. The contact angles of the transparent matrix 112 and the pixel regions 111 differ more than 10°, In the first embodiment, the contact angles of the transparent matrix 112 and the pixel regions 111 differ more than 50°.

Referring to FIG. 3B, an inkjet printing process is performed to inject color ink 41 including red ink 411, green ink 412 and blue ink 413 to the pixel regions 111 defined by the transparent matrix 112, a nozzle 31 injects the color ink 41. The color ink 41 can spread homogeneously on the surface of the pixel regions 111 for the surface of the pixel regions 111 that are hydrophilic. The hydrophobic function of the transparent matrix 112 mainly separates different colors of the ink, for the transparent matrix 112 so the color ink 41 in each of the pixel regions 111 cannot overflow to the adjacent pixel regions. In the first embodiment, the color ink 41 can be a UV-curing ink containing a pigment providing the color, resin adhesive, photopolymerization initiation, dispersing agent and other additives. The pigment in red ink 411 can be naphthol red pigment or azo condensation pigment, the pigment in green ink 412 can be phthalocyanine pigments, and the pigment in blue ink 413 can be metal phthalocyanine.

Referring to FIG. 3C, the substrate 11 is exposed in ultraviolet radiation (UV) 51, the color ink 41 on the surface of the pixel regions 111 is cured by the UV 51. The substrate 11 is made of PC material, the fusion temperature of PC is about 260° C. to 340° C., and the high temperature resistance of PC material is weak. Therefore the color ink 41 is cured by the UV 51, the cured energy is less than 1000 mj/cm², In particular, in the first embodiment, the cured energy is less than 500 mj/cm². After cured by the UV, the color ink 41 forms a color filter stacked on the surface of the pixel regions 111. The thickness of the color filter can be controlled in 0.110 microns by controlling the amount of the color ink 41 injected by the nozzle 31.

In another embodiment, the color ink 41 also can be a low temperature curing ink containing pigment providing the color, resin glue, thermal polymerization initiation, dispersing agent and other additives. In this embodiment, the thermocuring temperature of the color ink 41 is less than 100° C.

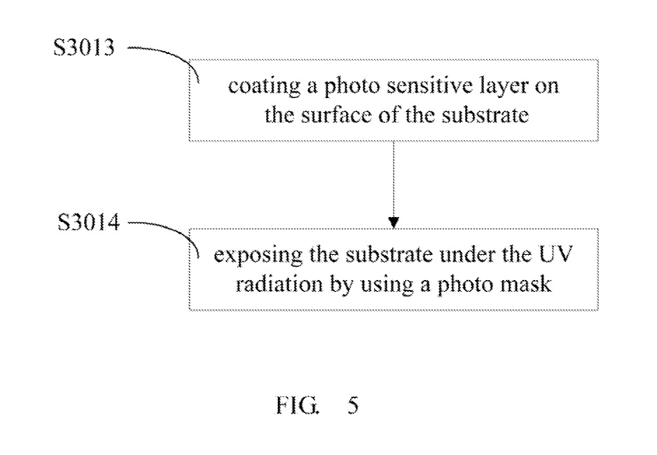

Referring to FIG. 5, a sub-flowchart of the step 301 in FIG. 1 is disclosed according to a second embodiment.

In step S3013, coating a photo sensitive layer on the surface of the substrate.

In step S3014, shielding some portion of the substrate by a photo mask and exposing other portion in a UV.

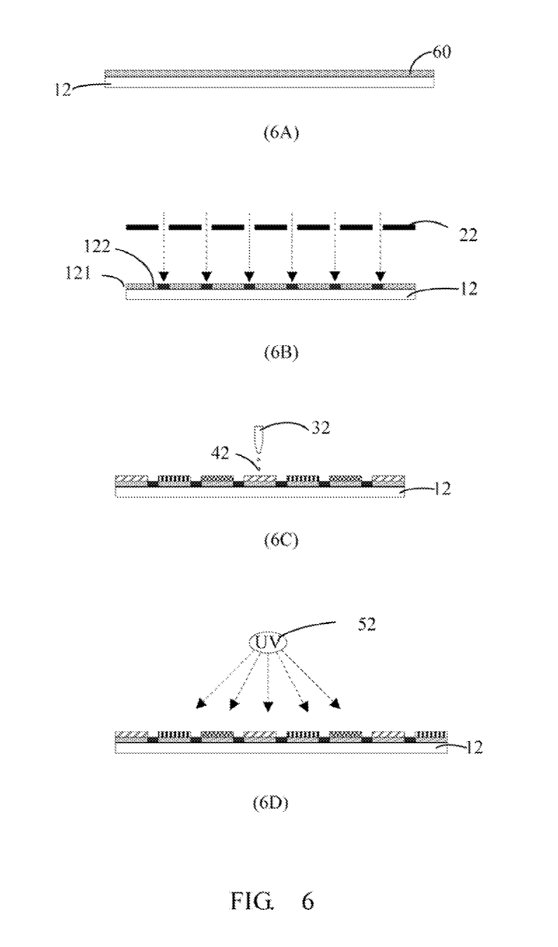

FIGS. 6A-6D are schematic cross-sectional views illustrating a process of fabricating a color filter according to the second embodiment.

Referring to FIG. 6A, in the second embodiment, a substrate 12 is also made of flexible plastic with high intensity. A photo sensitive layer 60 is coated on the surface of the substrate 12. In this embodiment, the photo sensitive layer 60 can be a layer of photo sensitive resin containing resin adhesive, photopolymerization initiation, dispersing agent, antioxidant, UV-absorber and other additives.

Referring to FIG. 6B, the substrate 12 is exposed under UV by using a photo mask 22. The surface of the photo sensitive layer 60, which is not shielded by the photo mask 22 photopolymerizes under the UV, to form a transparent matrix 122 with high hydrophobicity and low surface energy. The transparent matrix 122 divides the substrate 12 to a plurality of pixel regions 121. The transparent matrix 122 and the pixel regions 121 have different wettability, in this embodiment, the transparent matrix 122 is hydrophobic and the pixel regions 121 is hydrophilic, and the contact angles of the transparent matrix 122 and the pixel regions 121 differ more than 30°.

Referring to FIGS. 6C and 6D, the step 302 and step 303 is similar to the first embodiment. A nozzle 32 injects the color ink 42 to the pixel regions 121, and then the color ink 42 is cured under the UV. In the second embodiment, the cured energy is less than 150 mj/cm², the thickness of the color filter is controlled within 0.1˜10 microns.

In another embodiment, an etch process or blasting process can be applied to form the transparent-matrix with high hydrophobicity and low surface energy in the step 301.

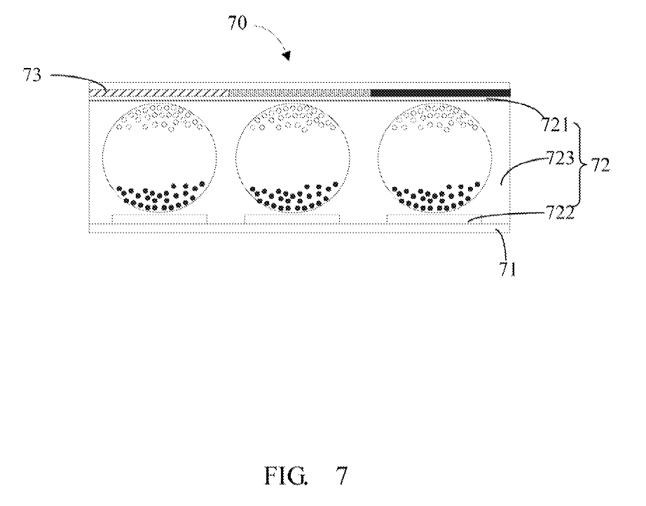

Referring to FIG. 7, an electronic paper (E-paper) 70 includes a substrate 71, a display layer 72 and a color filter 73 with a flexible substrate. The display layer 72 includes a first electrode 721, an electrophoretic ink layer 723, and a second electrode 722, voltage applied to the first electrode 721 and the second electrode 722 causes the electrophoretic ink layer 723 to change the optical state, to display the content on the E-paper. Because of the color filter has a flexible substrate, the color filter can be stacked on the electrophoretic display without generating inner gas-holes.

It is to be understood, however, that even though numerous characteristics and advantages of the present disclosure have been set forth in the foregoing description, together with details of the structure and function of the present disclosure, the present disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. A method of fabricating a color filter, comprising:
forming a transparent-matrix on a flexible and transparent substrate for dividing the substrate to a plurality of pixel regions, wherein the transparent-matrix and the pixel regions are different in wettability;
printing the a plurality of pixel regions with color ink; and
curing the color ink to form a plurality of color filters on the surface of the substrate.

2. The method according to claim 1, wherein the step of forming a transparent-matrix on a flexible and transparent substrate comprises:
placing the substrate in a plasma gas of carbon tetrafluoride; and
shielding some portion of the substrate by a photo mask and exposing other portion in the plasma gas of carbon tetrafluoride to form the matrix.

3. The method according to claim 2, wherein the substrate is exposed in an ultraviolet radiation (UV) environment.

4. The method according to claim 1, wherein the step of forming a transparent-matrix on a flexible and transparent substrate comprises:
coating a photo sensitive layer on the surface of the substrate; and
shielding some portion of the substrate by a photo mask and exposing other portion in a UV to form the matrix.

5. The method according to claim 4, wherein the photo sensitive layer is a layer of photo sensitive resin.

6. The method according to claim 1, wherein two contact angles of the transparent matrix and the pixel regions differ more than 10°.

7. The method according to claim 6, wherein two contact angles of the transparent matrix and the pixel regions differ more than 50°.

8. The method according to claim 1, wherein the substrate is made of polyisoprene (PI), polycarbonate (PC), or polyethylene terephthalate (PET).

9. The method according to claim 1, wherein the color ink is a UV-curing ink.

10. The method according to claim 9, wherein the step of curing the color ink is UV-curing.

11. The method according to claim 10, wherein a cured energy of the UV-curing is less than 1000 mj/cm².

12. The method according to claim 1, wherein a cured energy of the UV-curing is less than 500 mj/cm².

13. The method according to claim 1, wherein the color ink is a low temperature curing ink.

14. The method according to claim 13, wherein the step of curing the color ink comprises thermocuring.

15. The method according to claim 14, wherein the thermocuring temperature is less than 100° C.
